(19) United States
(12) Patent Application Publication
(10) Pub. No.: US 2026/0196989 A1
(43) Pub. Date: Jul. 9, 2026

(54) LOW POWER FLIP-FLOP AND INTEGRATED CIRCUIT INCLUDING THE SAME

(71) Applicant: Samsung Electronics Co., Ltd., Suwon-si (KR)

(72) Inventors: Bomin Joo, Suwon-si (KR); Minji Kim, Suwon-si (KR); Taejung Seol, Suwon-si (KR); Jaebeom Yang, Suwon-si (KR); Dalhee Lee, Suwon-si (KR)

(21) Appl. No.: 19/312,762

(22) Filed: Aug. 28, 2025

(30) Foreign Application Priority Data
Jan. 3, 2025 (KR) 10-2025-0000931

(51) Int. Cl. H03K 3/037

(52) U.S. Cl. CPC H03K 3/0372

(57) ABSTRACT

An example of flip-flop includes a master latch and a slave latch, and the master latch may include a first circuit configured to generate, based on a data input, a first data signal complementary to the data input and a second circuit configured to generate, based on a clock input and the first data signal, a second data signal complementary to the first data signal and a clock signal complementary to the clock input, and the slave latch may be configured to receive the clock signal through a first node and to generate a data output by latching a third data signal complementary to the second data signal based on the clock input, the second data signal, and the clock signal, and the second circuit may be configured to float the first node based on the first data signal and the third data signal.

### CROSS-REFERENCE TO RELATED APPLICATIONS

This application claims the benefit of priority under 35 U.S.C. § 119 to Korean Patent Application No. 10-2025-0000931, filed on Jan. 3, 2025, in the Korean Intellectual Property Office, the disclosure of which is incorporated herein by reference in its entirety.

### BACKGROUND

An integrated circuit that processes digital signals may include flip-flops. The flip-flops may latch an input based on clocks and may output the latched input. The flip-flops may include transistors and may have various structures according to applications. The integrated circuit may include numerous flip-flops, and the power consumption of flip-flops may be significant for the power consumption of the integrated circuit.

### SUMMARY

Example implementations relate to a flip-flop, and more particularly, to a low power flip-flop and an integrated circuit including the same.

Aspects of the present disclosure provide a flip-flop with low power consumption and an integrated circuit including the same.

According to an aspect of the present disclosure, a flip-flop includes a master latch and a slave latch, and the master latch may include a first circuit configured to generate, based on a data input, a first data signal complementary to the data input and a second circuit configured to generate, based on a clock input and the first data signal, a second data signal complementary to the first data signal and a clock signal complementary to the clock input, and the slave latch may be configured to receive the clock signal through a first node and to generate a data output by latching a third data signal complementary to the second data signal based on the clock input, the second data signal, and the clock signal, and the second circuit may be configured to float the first node based on the first data signal and the third data signal.

According to another aspect of the present disclosure, a flip-flop is configured to generate a data output by latching a data input based on a clock input, the flip-flop including a master latch configured to generate, based on the data input and the clock input, a first data signal complementary to the data input, a second data signal complementary to the first data signal, and a clock signal complementary to the clock input and a slave latch configured to receive the clock signal through a first node and to generate the data output by latching a third data signal complementary to the second data signal based on the clock input, the second data signal, and the clock signal, and the master latch may be configured to float the first node based on the first data signal and the third data signal.

According to another aspect of the present disclosure, a method includes generating a data output by latching a data input based on a clock input, the method including generating, based on the data input, a first data signal, generating, based on the clock input and the first data signal, a second data signal complementary to the first data signal and a clock signal complementary to the clock input, and generating the data output by latching a third data signal complementary to the second data signal based on the clock input, the second data signal, and the clock signal, and generating the second data signal and the clock signal may include floating, based on the first data signal and the third data signal, a first node at which the clock signal is generated.

### BRIEF DESCRIPTION OF THE FIGURES

These and/or other aspects, features, and advantages of the present disclosure will become apparent and more readily appreciated from the following description of example implementations, taken in conjunction with the accompanying drawings of which:

FIG. 1 is a block diagram illustrating a flip-flop according to an example implementation;

FIG. 2 is a circuit diagram illustrating a slave latch according to an example implementation;

FIGS. 3A and 3B are block diagrams illustrating examples of a master latch according to example implementations;

FIGS. 4A and 4B are circuit diagrams illustrating examples of a first circuit according to example implementations;

FIGS. 5A and 5B are circuit diagrams illustrating examples of a second circuit according to example implementations;

FIG. 6 is a timing diagram illustrating an operation of a flip-flop according to an example implementation;

FIG. 7 is a flowchart illustrating an operation of a flip-flop according to an example implementation;

FIG. 8 is a flowchart illustrating an operation of a flip-flop according to an example implementation;

FIG. 9 is a flowchart illustrating an operation of a flip-flop according to an example implementation;

FIG. 10 is a flowchart illustrating a method of manufacturing an integrated circuit according to an example implementation; and

FIG. 11 is a block diagram illustrating a system on chip according to an example implementation.

### DETAILED DESCRIPTION

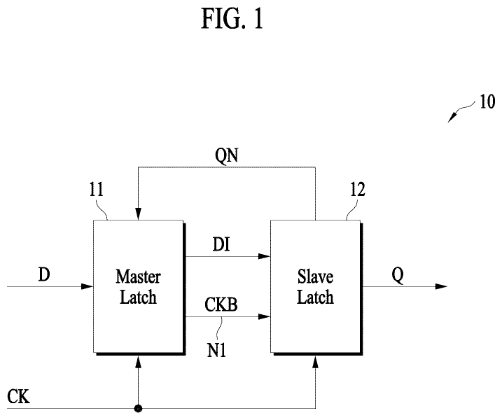

FIG. 1 is a block diagram illustrating a flip-flop 10 according to an example implementation. In some example implementations, the flip-flop 10 may be included in an integrated circuit manufactured by a semiconductor process. As illustrated in FIG. 1, the flip-flop 10 may include a master latch 11 and a slave latch 12. Herein, unless otherwise described, it is assumed that signals are active-high signals that have logic high when activated and have logic low when deactivated, but example implementations are not limited thereto, and it is noted that signals may be active-low signals that have logic low when activated. Herein, logic high may correspond to a positive supply voltage (VDD) and may be represented as a high level or “1”. In addition, logic low may correspond to a negative supply voltage (VSS) and may be represented as a low level or “0”.

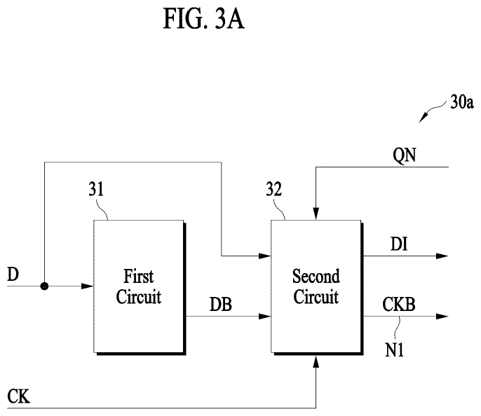

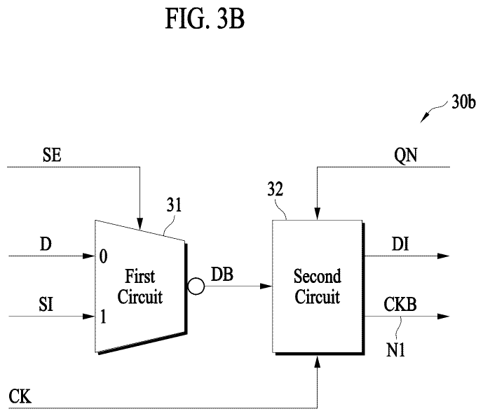

As illustrated in FIG. 1, the flip-flop 10 may receive a clock input CK and a data input D and may output a data output Q. The flip-flop 10 may latch the data input D based on the clock input CK and may generate the data output Q corresponding to the data input D that is latched. In some example implementations, as described below with reference to FIG. 3B, the flip-flop 10 may additionally receive a scan input SI and a scan enable input SE, and when the scan enable input SE is activated, may support a scan chain by outputting the data output Q corresponding to the scan input SI.

In some example implementations, the flip-flop 10 may be a single-ended type and may generate a data signal, for example, a first data signal DB of FIG. 3A, which is complementary to the data input D. In some example implementations, the flip-flop 10 may be a differential type and may receive an inverted data input in addition to the data input D and may generate the data output Q and an inverted data output. The flip-flop 10 may be a positive edge triggered flip-flop that latches the data input D in response to a rising edge of the clock input CK and may also be a negative edge triggered flip-flop that latches the data input D in response to a falling edge of the clock input CK. Herein, it is assumed that the flip-flop 10 is the positive edge triggered flip-flop, but it is noted that example implementations are not limited thereto.

The master latch 11 may receive the data input D, the clock input CK, and a third data signal QN and may generate a second data signal DI and a clock signal CKB. The first data signal DB may be complementary to the data input D, the second data signal DI may be complementary to the first data signal DB, and the third data signal QN may be complementary to the second data signal DI. In addition, the clock signal CKB may be complementary to the clock input CK. Herein, a second signal complementary to a first signal may refer to a signal corresponding to an inverted version of the first signal under a condition. For example, the second signal may be identical to an inverted version of the first signal and may transition opposite to the first signal in response to a transition of the first signal under a predetermined condition.

The flip-flop 10 may be included in an integrated circuit that processes digital signals. In the flip-flop 10, the switching of the data input D and signals depending thereon, for example, the first data signal DB, the second data signal DI, the third data signal QN, and the data output Q, may be relatively less (for example, less than 20 percent (%)), whereas the clock input CK and a signal depending thereon, for example, the clock signal CKB, may frequently repeat rising and falling. Reducing power consumption caused by the clock signal CKB generated in the flip-flop 10 may be significant for reducing the power consumption of the flip-flop 10.

As described below with reference to the drawings, the master latch 11 may generate, based on the data input D and the clock input CK, the second data signal DI complementary to the first data signal DB and the clock signal CKB complementary to the clock input CK. In addition, the master latch 11 may float, based on the first data signal DB and the third data signal QN, a first node N1 at which the clock signal CKB is generated. Accordingly, an unnecessary transition of the clock signal CKB may be omitted, and the power consumption of the flip-flop 10 and the integrated circuit including the same may be reduced. Examples of the master latch 11 will be described below with reference to FIGS. 3A and 3B.

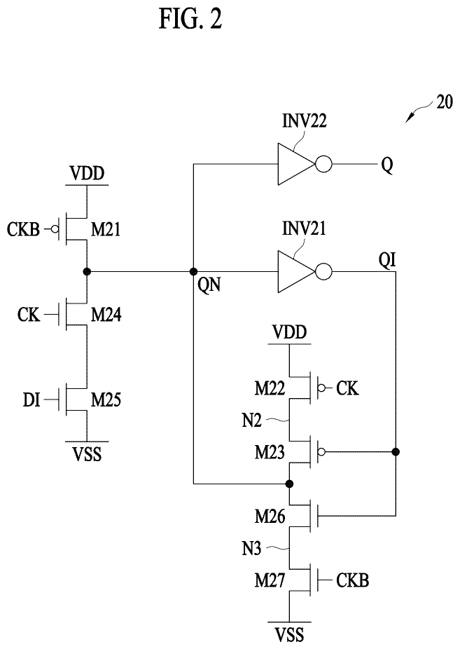

The slave latch 12 may receive the clock input CK and the second data signal DI and may receive the clock signal CKB through the first node N1. The slave latch 12 may generate the data output Q by latching the third data signal QN based on the clock input CK, the second data signal DI, and the clock signal CKB. As described above, the third data signal QN may be provided to the master latch 11, and the master latch 11 may use the third data signal QN to float the first node N1. An example of the slave latch 12 will be described below with reference to FIG. 2.

FIG. 2 is a circuit diagram illustrating a slave latch 20 according to an example implementation. For example, the circuit diagram of FIG. 2 illustrates an example of the slave latch 12 of FIG. 1. As described above with reference to FIG. 1, the slave latch 20 may generate the data output Q by latching the third data signal QN based on the clock input CK, the second data signal DI, and the clock signal CKB. It is noted that the slave latch 12 of FIG. 1 is not limited to the slave latch 20 of FIG. 2.

Referring to FIG. 2, the slave latch 20 may include first to seventh transistors M21 to M27, a first inverter INV21, and a second inverter INV22. The first to third transistors M21 to M23 may be p-channel field effect transistors (PFETs), and the fourth to seventh transistors may be n-channel field effect transistors (NFETs). In some example implementations, the second transistor M22 and the seventh transistor M27 may be shared with the master latch 11 of FIG. 1. Accordingly, the second transistor M22 and the seventh transistor M27 may be omitted from the master latch 11 or the slave latch 20, and the master latch 11 and the slave latch 20 may be connected each other through a second node N2 and a third node N3.

The first transistor M21, the fourth transistor M24, and the fifth transistor M25 may be connected in series between a first power node and a second power node. The first transistor M21 may receive the clock signal CKB, the fourth transistor M24 may receive the clock input CK, and the fifth transistor M25 may receive the second data signal DI. In some example implementations, the fourth transistor M24 and the fifth transistor M25 may be connected each other in series in an order different from an order illustrated in FIG. 2. As illustrated in FIG. 2, the third data signal QN may be generated at a node connected to the first transistor M21 and the fourth transistor M24. In other words, the third data signal QN may be precharged to a high level when the clock signal CKB is at a low level, and the third data signal QN may correspond to an inverted version of the second data signal DI when the clock signal CKB and the clock input CK are at a high level.

The first inverter INV21 and the second inverter INV22 may generate a data output signal QI and the data output Q, respectively, by inverting the third data signal QN. Herein, an inverter such as the first inverter INV21 and the second inverter INV22 may include a PFET and an NFET connected in series between a first power node to which a positive supply voltage VDD is applied and a second power node to which a negative supply voltage VSS is applied.

The second transistor M22, the third transistor M23, the sixth transistor M26, and the seventh transistor M27 may be connected in series between the first power node and the second power node. The second transistor M22 may receive the clock input CK, the third transistor M23 and the sixth transistor M26 may receive the data output signal QI, and the seventh transistor M27 may receive the clock signal CKB. Accordingly, when the clock input CK is at a low level and the clock signal CKB is at a high level, the second transistor M22, the third transistor M23, the sixth transistor M26, and the seventh transistor M27 may operate as an inverter and may generate the third data signal QN by inverting the data output signal QI.

FIGS. 3A and 3B are block diagrams illustrating examples of a master latch according to example implementations. For example, each of the block diagrams of FIGS. 3A and 3B illustrates an example of the master latch 11 of FIG. 1. As described above with reference to FIG. 1, each of master latches 30a and 30b may generate the first data signal DB, the second data signal DI, and the clock signal CKB based on the data input D and the clock input CK and may float, based on the first data signal DB and the third data signal QN, the first node N1 from which the clock signal CKB is outputted. Hereinafter, overlapping description will be omitted from descriptions of FIGS. 3A and 3B.

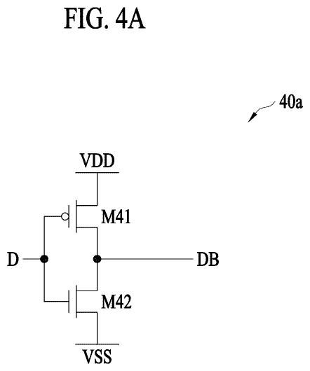

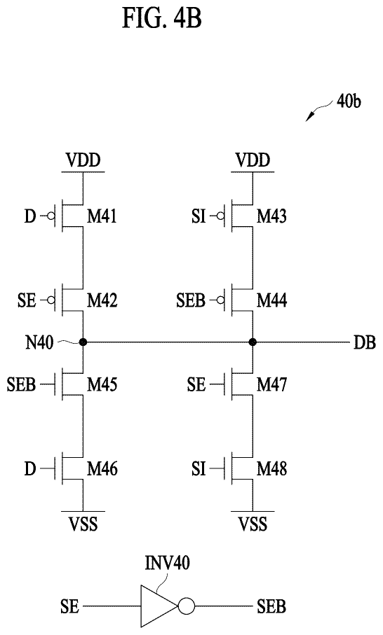

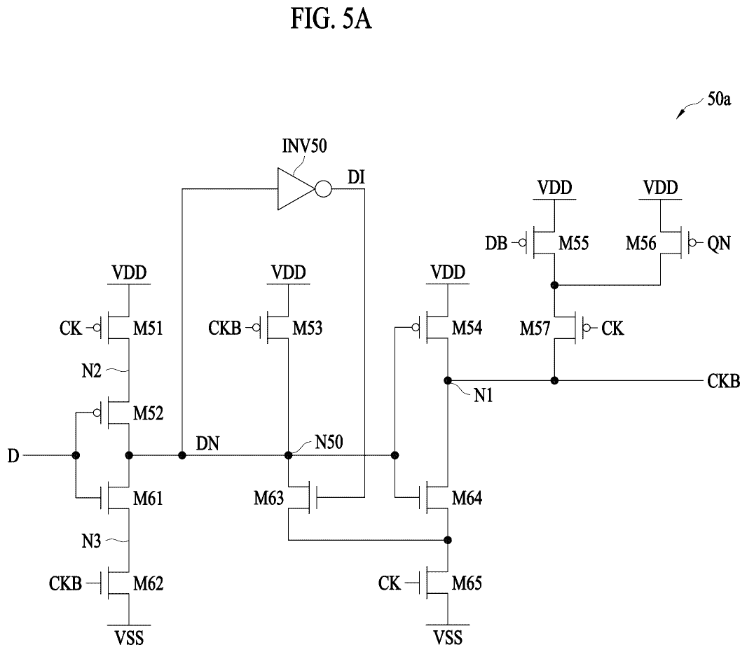

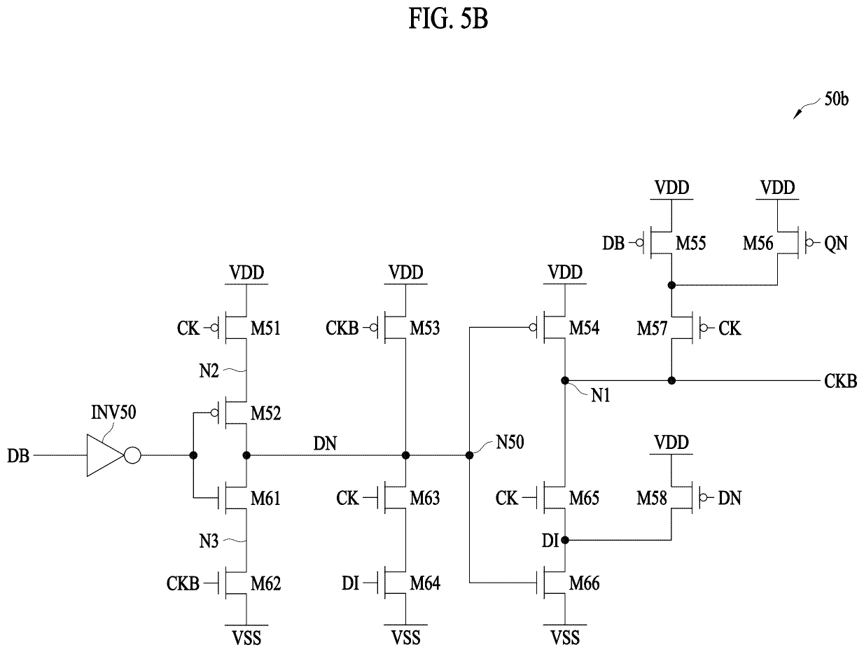

Referring to FIG. 3A, the master latch 30a may include a first circuit 31 and a second circuit 32. The first circuit 31 may generate, based on the data input D, the first data signal DB complementary to the data input D. An example of the first circuit 31 will be described below with reference to FIG. 4A. The second circuit 32 may generate, based on the data input D, the clock input CK, and the first data signal DB, the second data signal DI complementary to the first data signal DB and the clock signal CKB complementary to the clock input CK. In addition, the second circuit 32 may float, based on the first data signal DB and the third data signal QN, the first node N1 at which the clock signal CKB is generated. Examples of the second circuit 32 will be described below with reference to FIGS. 5A and 5B.

Referring to FIG. 3B, the master latch 30b may include the first circuit 31 and the second circuit 32. When compared to the master latch 30a of FIG. 3A, the master latch 30b may additionally receive the scan input SI and the scan enable input SE. An integrated circuit may provide a scan chain for debugging or the like, and when the scan chain is enabled, in other words, when the scan enable input SE is activated, a flip-flop may output the data output Q corresponding to the scan input SI instead of the data input D.

The first circuit 31 may receive the data input D, the scan input SI, and the scan enable input SE and may select one of the data input D and the scan input SI according to the scan enable input SE. For example, as illustrated in FIG. 3B, the scan enable input SE may be an active-high signal, and the first circuit 31 may select the data input D in response to the scan enable input SE that is at a low level and may select the scan input SI in response to the scan enable input SE that is at a high level. The first circuit 31 may generate the first data signal DB by inverting an input selected from the data input D and the scan input SI. An example of the first circuit 31 will be described below with reference to FIG. 4B.

The second circuit 32 may generate, based on the clock input CK and the first data signal DB, the second data signal DI complementary to the first data signal DB and the clock signal CKB complementary to the clock input CK. In addition, the second circuit 32 may float, based on the first data signal DB and the third data signal QN, the first node N1 at which the clock signal CKB is generated. Examples of the second circuit 32 will be described below with reference to FIGS. 5A and 5B.

FIGS. 4A and 4B are circuit diagrams illustrating examples of a first circuit according to example implementations. For example, the circuit diagram of FIG. 4A illustrates an example of the first circuit 31 of FIG. 3A, and the circuit diagram of FIG. 4B illustrates an example of the first circuit 31 of FIG. 3B.

Referring to FIG. 4A, a first circuit 40a may include a first transistor M41 that is a PFET and a second transistor M42 that is an NFET. The first transistor M41 and the second transistor M42 may be connected in series between a first power node and a second power node and may receive the data input D. Accordingly, the first circuit 40a may function as an inverter and may generate the first data signal DB by inverting the data input D.

Referring to FIG. 4B, a first circuit 40b may include first to eighth transistors M41 to M48 and an inverter INV40. The inverter INV40 may generate a scan enable signal SEB by inverting the scan enable input SE. The first to fourth transistors M41 to M44 may be PFETs, and the fifth to eighth transistors M45 to M48 may be NFETs.

The first transistor M41 and the second transistor M42 may be connected in series between a first power node and a node N40 at which the first data signal DB is generated and may receive the data input D and the scan enable input SE, respectively. In some example implementations, the first transistor M41 and the second transistor M42 may be connected each other in series in an order different from an order illustrated in FIG. 4B. The fifth transistor M45 and the sixth transistor M46 may be connected in series between the node N40 and a second power node and may receive the scan enable signal SEB and the data input D, respectively. In some example implementations, the fifth transistor M45 and the sixth transistor M46 may be connected each other in series in an order different from an order illustrated in FIG. 4B.

The third transistor M43 and the fourth transistor M44 may be connected in series between the first power node and the node N40 at which the first data signal DB is generated and may receive the scan input SI and the scan enable signal SEB, respectively. In some example implementations, the third transistor M43 and the fourth transistor M44 may be connected each other in series in an order different from an order illustrated in FIG. 4B. The seventh transistor M47 and the eighth transistor M48 may be connected in series between the node N40 and the second power node and may receive the scan enable input SE and the scan input SI, respectively. In some example implementations, the seventh transistor M47 and the eighth transistor M48 may be connected each other in series in an order different from an order illustrated in FIG. 4B. Hereinafter, the first circuit 31 of FIG. 3A or the first circuit 31 of FIG. 3B, which receives the scan enable input SE that is deactivated, is mainly described, but it is noted that example implementations are not limited thereto.

FIGS. 5A and 5B are circuit diagrams illustrating examples of a second circuit according to example implementations. For example, each of the circuit diagrams of FIGS. 5A and 5B illustrates an example of the second circuit 32 of FIGS. 3A and 3B. As described above with reference to FIGS. 3A and 3B, each of second circuits 50a and 50b of FIGS. 5A and 5B may generate, based on the clock input CK and the first data signal DB/the data input D, the second data signal DI complementary to the first data signal DB and the clock signal CKB complementary to the clock input CK. It is noted that the second circuit 32 of FIGS. 3A and 3B is not limited to the second circuits 50a and 50b of FIGS. 5A and 5B.

Referring to FIG. 5A, the second circuit 50a may include a first inverter INV50, first to seventh transistors M51 to M57, and eleventh to fifteenth transistors M61 to M65. The first to seventh transistors M51 to M57 may be PFETs, and the eleventh to fifteenth transistors M61 to M65 may be NFETs. The first inverter INV50 may generate the second data signal DI by inverting a fourth data signal DN.

The first transistor M51 and the second transistor M52 may be connected each other in series between a first power node and a node N50 at which the fourth data signal DN is generated and may receive the clock input CK and the data input D, respectively. In some example implementations, the first transistor M51 and the second transistor M52 may be connected each other in series in an order different from an order illustrated in FIG. 5A. The eleventh transistor M61 and the twelfth transistor M62 may be connected each other in series between the node N50 and a second power node and may receive the data input Dand the clock signal CKB, respectively. The eleventh transistor M61 and the twelfth transistor M62 may be connected each other in series in an order different from an order illustrated in FIG. 5A. The fourth data signal DN may be generated at the node N50 connected to the second transistor M52 and the eleventh transistor M61. Accordingly, the first transistor M51, the second transistor M52, the eleventh transistor M61, and the twelfth transistor M62 may function as an inverter when the clock input CK is at a low level and the clock signal CKB is at a high level, and the fourth data signal DN may be complementary to the data input D.

As described above with reference to FIG. 2, the first transistor M51 and the twelfth transistor M62 may be shared with the slave latch 20 of FIG. 2. Accordingly, one of the second transistor M22 of FIG. 2 and the first transistor M51 of FIG. 5A may be omitted, and the slave latch 20 and the second circuit 50a may be connected each other through the second node N2. In addition, one of the seventh transistor M27 of FIG. 2 and the twelfth transistor M62 of FIG. 5A may be omitted, and the slave latch 20 and the second circuit 50a may be connected each other through the third node N3.

The third transistor M53, the thirteenth transistor M63, and the fifteenth transistor M65 may be connected each other in series between the first power node and the second power node and may receive the clock signal CKB, the second data signal DI, and the clock input CK, respectively. The fourth data signal DN may be generated at the node N50 connected to the third transistor M53 and the thirteenth transistor M63. Accordingly, the node N50 may be pulled up by the clock signal CKB that is at a low level and may be pulled down by the second data signal DI and the clock input CK that are at a high level.

The fourth transistor M54, the fourteenth transistor M64, and the fifteenth transistor M65 may be connected each other in series between the first power node and the second power node, and the fourth transistor M54 and the fourteenth transistor M64 may receive the fourth data signal DN. The clock signal CKB may be generated at the first node N1 connected to the fourth transistor M54 and the fourteenth transistor M64. Accordingly, the clock signal CKB may correspond to an inverted version of the fourth data signal DN when the clock input CK is at a high level.

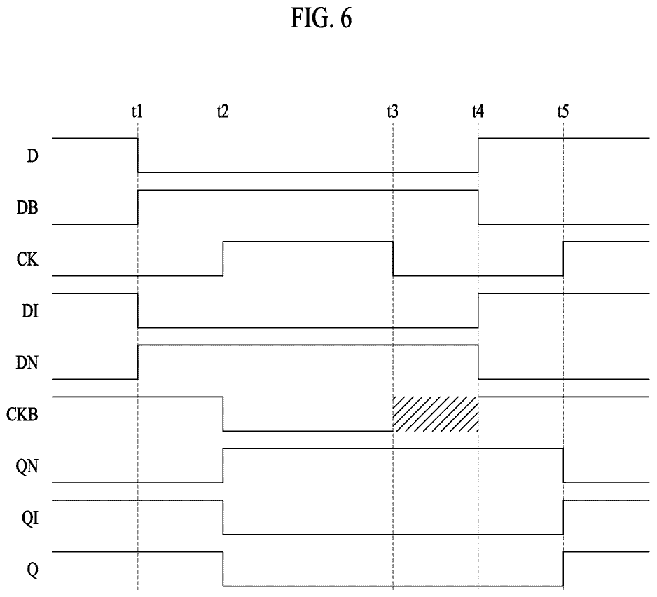

The fifth transistor M55 and the seventh transistor M57 may be connected each other in series between the first power node and the first node N1, and the sixth transistor M56 may be connected each other in parallel with the fifth transistor M55. The fifth transistor M55, the sixth transistor M56, and the seventh transistor M57 may receive the first data signal DB, the third data signal QN, and the clock input CK, respectively. Accordingly, when the first data signal DB, the third data signal QN, and the clock input CK are at a low level, the first node N1 may be pulled up. In contrast, when the first data signal DB and the third data signal QN are at a high level or the clock input CK is at a high level, a pull-up on the first node N1 may be blocked. Accordingly, as described below with reference to FIG. 6, in a state of the data input D and the data output Q at a low level, the first node N1 may be floated to prevent a pull-up on the first node N1, and thus, an unnecessary transition, in other words, a rising edge, of the clock signal CKB may be removed. In some example implementations, a pair of the fifth transistor M55 and the sixth transistor M56 connected each other in parallel and the seventh transistor M57 may be connected each other in series in an order different from an order illustrated in FIG. 5A.

Referring to FIG. 5B, the second circuit 50b may include the first inverter INV50, first to eighth transistors M51 to M58, and eleventh to sixteenth transistors M61 to M66. The first to eighth transistors M51 to M58 may be PFETs, and the eleventh to sixteenth transistors M61 to M66 may be NFETs. The first inverter INV50 may receive the first data signal DB and may provide an inverted version of the first data signal DB to the second transistor M52 and the eleventh transistor M61.

The first transistor M51 and the second transistor M52 may be connected each other in series between a first power node and the node N50 at which the fourth data signal DN is generated and may receive the clock input CK and an output of the first inverter INV50, respectively. In some example implementations, the first transistor M51 and the second transistor M52 may be connected each other in series in an order different from an order illustrated in FIG. 5B. The eleventh transistor M61 and the twelfth transistor M62 may be connected each other in series between the node N50 and a second power node and may receive an output of the first inverter INV50 and the clock signal CKB, respectively. The eleventh transistor M61 and the twelfth transistor M62 may be connected each other in series in an order different from an order illustrated in FIG. 5B. The fourth data signal DN may be generated at the node N50 connected to the second transistor M52 and the eleventh transistor M61. Accordingly, the first transistor M51, the second transistor M52, the eleventh transistor M61, and the twelfth transistor M62 may function as an inverter when the clock input CK is at a low level and the clock signal CKB is at a high level, and the fourth data signal DN may be complementary to the data input D.

As described above with reference to FIG. 2, the first transistor M51 and the twelfth transistor M62 may be shared with the slave latch 20 of FIG. 2. Accordingly, one of the second transistor M22 of FIG. 2 and the first transistor M51 of FIG. 5B may be omitted, and the slave latch 20 and the second circuit 50b may be connected each other through the second node N2. In addition, one of the seventh transistor M27 of FIG. 2 and the twelfth transistor M62 of FIG. 5B may be omitted, and the slave latch 20 and the second circuit 50b may be connected each other through the third node N3. When the slave latch 20 of FIG. 2 shares two transistors with the second circuit 50a of FIG. 5A or the second circuit 50b of FIG. 5B, a flip-flop may include only four transistors that receive the clock input CK. Accordingly, input capacitance of the clock input CK may decrease, and the power consumption of the flip-flop may additionally decrease.

The third transistor M53, the thirteenth transistor M63, and the fourteenth transistor M64 may be connected each other in series between the first power node and the second power node and may receive the clock signal CKB, the clock input CK, and the second data signal DI, respectively. The fourth data signal DN may be generated at the node N50 connected to the third transistor M53 and the thirteenth transistor M63. Accordingly, the node N50 may be pulled up by the clock signal CKB that is at a low level and may be pulled down by the second data signal DI and the clock input CK that are at a high level. In some example implementations, the thirteenth transistor M63 and the fourteenth transistor M64 may be connected each other in series in an order different from an order illustrated in FIG. 5B.

The fourth transistor M54, the fifteenth transistor M65, and the sixteenth transistor M66 may be connected each other in series between the first power node and the second power node and may receive the fourth data signal DN, the clock input CK, and the fourth data signal DN, respectively. In addition, the fourth transistor M54 may be connected between the first power node and the first node N1, and the fifteenth transistor M65 and the sixteenth transistor M66 may be connected each other in series between the second power node and the first node N1. The clock signal CKB may be generated at the first node N1 connected to the fourth transistor M54 and the fifteenth transistor M65. The eighth transistor M58 may be connected between the first power node and a node connected to the fifteenth transistor M65 and the sixteenth transistor M66 and may receive the fourth data signal DN. The second data signal DI may be generated at a node connected to the eighth transistor M58, the fifteenth transistor M65, and the sixteenth transistor M66. By the eighth transistor M58 and the sixteenth transistor M66, the second data signal DI may correspond to an inverted version of the fourth data signal DN.

The fifth transistor M55 and the seventh transistor M57 may be connected each other in series between the first power node and the first node N1, and the sixth transistor M56 may be connected each other in parallel with the fifth transistor M55. The fifth transistor M55, the sixth transistor M56, and the seventh transistor M57 may receive the first data signal DB, the third data signal QN, and the clock input CK, respectively. Accordingly, when the first data signal DB, the third data signal QN, and the clock input CK are at a low level, the first node N1 may be pulled up. In contrast, when the first data signal DB and the third data signal QN are at a high level or the clock input CK is at a high level, a pull-up on the first node N1 may be blocked. Accordingly, as described below with reference to FIG. 6, in a state of the data input D and the data output Q at a low level, the first node N1 may be floated to prevent a pull-up on the first node N1, and thus, an unnecessary transition, in other words, a rising edge, of the clock signal CKB may be removed. In some example implementations, a pair of the fifth transistor M55 and the sixth transistor M56 connected each other in parallel and the seventh transistor M57 may be connected each other in series in an order different from an order illustrated in FIG. 5B.

FIG. 6 is a timing diagram illustrating an operation of a flip-flop according to an example implementation. The timing diagram of FIG. 6 illustrates the data input D, the first data signal DB, the clock input CK, the second data signal DI, the fourth data signal DN, the clock signal CKB, the third data signal QN, the data output signal QI, and the data output Q based on the passage of time. Hereinafter, FIG. 6 is described with reference to FIGS. 2 and 5A, but it may be understood that the second circuit 50b of FIG. 5B also operates similarly.

At time t1, a falling edge of the data input D may be generated while the clock input CK is at a low level. Accordingly, the first data signal DB may transition to a high level. Since the clock input CK is at the low level and the clock signal CKB is at a high level, the fourth data signal DN may transition to a high level due to the first data signal DB transitioned to the high level. The second data signal DI may transition to a low level due to the fourth data signal DN transitioned to the high level.

At time t2, a rising edge of the clock input CK may be generated. Due to the fourteenth transistor M64 of FIG. 5A receiving the fourth data signal DN that is at the high level and the fifteenth transistor M65 of FIG. 5A receiving the clock input CK transitioned to a high level, the first node N1 may be pulled down, and the clock signal CKB may transition to a low level. Due to the first transistor M21 of FIG. 2 receiving the clock signal CKB transitioned to the low level, the third data signal QN may transition to a high level. Due to the third data signal QN transitioned to the high level, the data output signal QI and the data output Q may transition to a low level.

At time t3, a falling edge of the clock input CK may be generated. Although the seventh transistor M57 of FIG. 5A receives the clock input CK transitioned to the low level, the first data signal DB and the third data signal QN are at the high level, in addition to the fourth data signal DN, and thus, a pull-up path of the first node N1 at which the clock signal CKB is generated may be all blocked. Accordingly, the first node N1 may be floated, and the clock signal CKB may enter into a high impedance state. In some example implementations, the clock signal CKB may be maintained at the low level. Consequently, a rising edge of the clock signal CKB may be omitted, and thus, unnecessary power consumption may be removed.

At time t4, a rising edge of the data input D may be generated while the clock input CK is at the low level. Accordingly, the first data signal DB may transition to a low level. Due to the seventh transistor M57 of FIG. 5A receiving the clock input CK that is at the low level and the fifth transistor M55 receiving the first data signal DB transitioned to the low level, the first node N1 may be pulled up, and the clock signal CKB may transition to the high level. Due to the eleventh transistor M61 of FIG. 5A receiving the data input D that is at a high level and the twelfth transistor M62 receiving the clock signal CKB transitioned to the high level, the fourth data signal DN may transition to a low level. Due to the fourth data signal DN transitioned to the low level, the second data signal DI may transition to a high level.

At time t5, the rising edge of the clock input CK may be generated. Due to the fourth transistor M24 of FIG. 2 receiving the clock input CK transitioned to the high level and the fifth transistor M25 receiving the second data signal DI that is at the high level, the third data signal QN may transition to a low level. Due to the third data signal QN transitioned to the low level, the data output signal QI and the data output Q may transition to a high level.

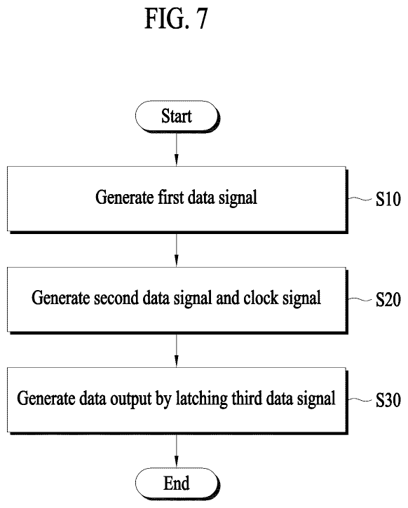

FIG. 7 is a flowchart illustrating an operation of a flip-flop according to an example implementation. Herein, an operation of a flip-flop may be referred to as a method of generating a data output by latching a data input based on a clock input or simply as a method. As illustrated in FIG. 7, the method may include a plurality of operations S10, S20, and S30. In some example implementations, the method of FIG. 7 may be performed by the flip-flop 10 of FIG. 1. Hereinafter, FIG. 7 is described with reference to FIG. 1.

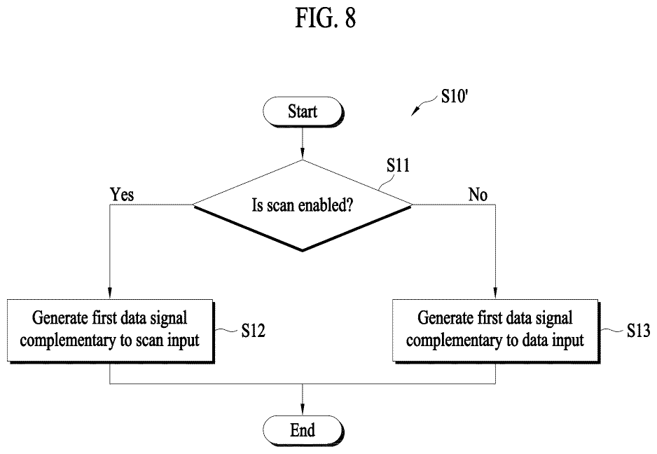

Referring to FIG. 7, in operation S10, the first data signal DB may be generated. For example, the master latch 11 may generate, based on the data input D, the first data signal DB complementary to the data input D. An example of operation S10 will be described below with reference to FIG. 8.

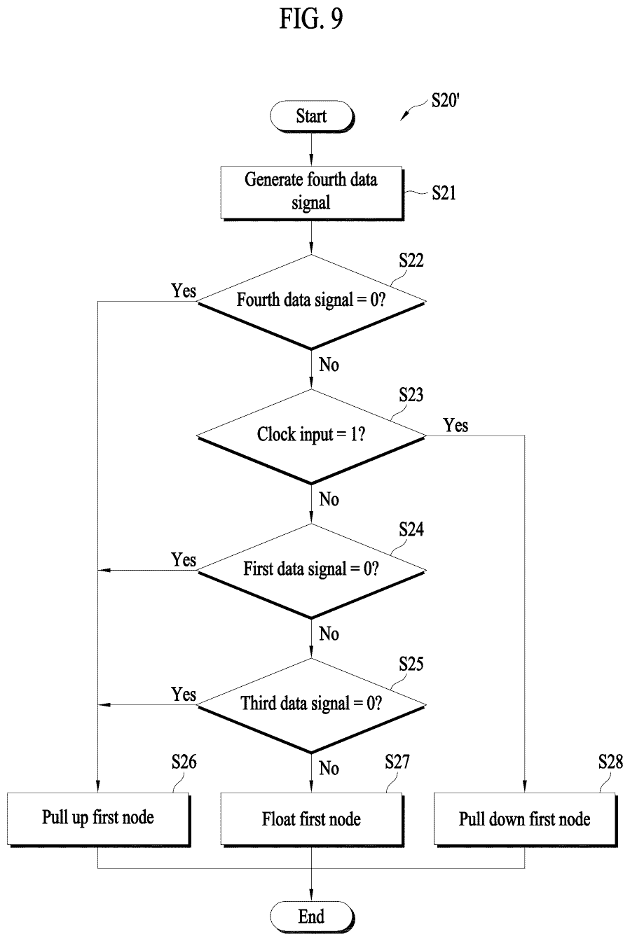

In operation S20, the second data signal DI and the clock signal CKB may be generated. For example, the master latch 11 may generate, based on the clock input CK and the first data signal DB, the second data signal DI complementary to the first data signal DB and the clock signal CKB complementary to the clock input CK. As described above with reference to the drawings, the master latch 11 may float the first node N1, at which the clock signal CKB is generated, based on the first data signal DB and the third data signal QN generated in operation S30 to be described below. Accordingly, a transition (for example, a rising edge) of the clock signal CKB may be prevented, and the power consumption of the flip-flop may decrease. An example of operation S20 will be described below with reference to FIG. 9.

In operation S30, the data output Q may be generated by latching the third data signal QN. For example, the slave latch 12 may generate the data output Q by latching the third data signal QN complementary to the second data signal DI based on the clock input CK, the second data signal DI, and the clock signal CKB.

FIG. 8 is a flowchart illustrating an operation of a flip-flop according to an example implementation. For example, the flowchart of FIG. 8 illustrates an example of operation S10 of FIG. 7. As described above with reference to FIG. 7, in operation S10′ of FIG. 8, the first data signal DB complementary to the data input D may be generated. As illustrated in FIG. 8, operation S10′ may include a plurality of operations S11, S12, and S13. In some example implementations, operation S10′ may be performed by the first circuit 31 of FIG. 3B. Hereinafter, FIG. 8 is described with reference to FIG. 3B.

Referring to FIG. 8, in operation S11, whether scan is enabled may be determined. For example, the first circuit 31 may receive the scan enable input SE and may determine whether scan is enabled based on the scan enable input SE. When scan is enabled, in other words, when the scan enable input SE that is activated is received, operation S12 may be subsequently performed, whereas, when scan is disabled, in other words, when the scan enable input SE that is deactivated is received, operation S13 may be subsequently performed.

When scan is enabled, the first data signal DB complementary to the scan input SI may be generated in operation S12. In contrast, when scan is disabled, the first data signal DB complementary to the data input D may be generated in operation S13. The first circuit 31 may select one of the data input D and the scan input SI according to the scan enable input SE and may generate the first data signal DB corresponding to an inverted version of a selected input.

FIG. 9 is a flowchart illustrating an operation of a flip-flop according to an example implementation. For example, the flowchart of FIG. 9 illustrates an example of operation S20 of FIG. 7. As described above with reference to FIG. 7, in operation S20′ of FIG. 9, the clock signal CKB complementary to the clock input CK may be generated. As illustrated in FIG. 9, operation S20′ may include a plurality of operations S21 to S28. In some example implementations, operation S20′ may be performed by the second circuit 32 of FIG. 3A. Hereinafter, FIG. 9 is described with reference to FIG. 3A.

Referring to FIG. 9, in operation S21, the fourth data signal DN may be generated. For example, the second circuit 32 may generate the fourth data signal DN by inverting a signal, which is inverted from the first data signal DB, based on the clock input CK and the clock signal CKB.

In operation S22, whether the fourth data signal DN is at a low level may be determined, and when the fourth data signal DN is at the low level, the first node N1 may be pulled up in operation S26. For example, the second circuit 32 may include a PFET (for example, M54 of FIG. 5A) connected between a first power node and the first node N1 and receiving the fourth data signal DN. The PFET may pull up the first node N1 in response to the fourth data signal DN that is at the low level. Accordingly, the clock signal CKB may have a high level.

When the fourth data signal DN is at a high level, whether the clock input CK is at a high level may be determined in operation S23. When the clock input CK is at the high level, the first node N1 may be pulled down in operation S28. For example, the second circuit 32 may include two NFETs (for example, M64 and M65 of FIG. 5A) connected each other in series with one receiving the fourth data signal DN and the other receiving the clock input CK. The two NFETs may pull down the first node N1 in response to the fourth data signal DN and the clock input CK that are at the high level. Accordingly, the clock signal CKB may have a low level.

When the clock input CK is at a low level, whether the first data signal DB is at a low level may be determined in operation S24. When the first data signal DB is at the low level, the first node N1 may be pulled up in operation S26. For example, the second circuit 32 may include two PFETs (for example, M55 and M57 of FIG. 5A) connected each other in series with one receiving the first data signal DB and the other receiving the clock input CK. The two PFETs may pull up the first node N1 in response to the first data signal DB and the clock input CK that are at the low level. Accordingly, the clock signal CKB may have the high level.

When the first data signal DB is at a high level, whether the third data signal QN is at a low level may be determined in operation S25. When the third data signal QN is at the low level, the first node N1 may be pulled up in operation S26. For example, the second circuit 32 may include two PFETs (for example, M56 and M57 of FIG. 5A) connected each other in series with one receiving the third data signal QN and the other receiving the clock input CK. The two PFETs may pull up the first node N1 in response to the third data signal QN and the clock input CK that are at the low level. Accordingly, the clock signal CKB may have the high level.

When the third data signal QN is at a high level, the first node N1 may be floated in operation S27. For example, the second circuit 32 may include two PFETs connected each other in parallel between a first power node and a PFET that receives the clock input CK, with one receiving the first data signal DB and the other receiving the third data signal QN. Accordingly, despite the clock input CK at the low level, a pull-up path of the first node N1 may be blocked due to the first data signal DB and the third data signal QN that are at the high level, and the first node N1 may be floated. Therefore, the clock signal CKB may enter into a high impedance state, and a rising edge of the clock signal CKB may be removed.

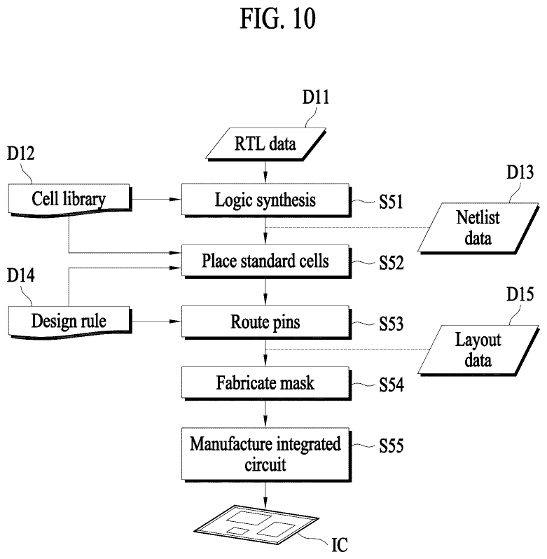

FIG. 10 is a flowchart illustrating a method of manufacturing an integrated circuit IC according to an example implementation. Specifically, the flowchart of FIG. 10 illustrates an example of the method of manufacturing the integrated circuit IC including standard cells. A standard cell is a unit of layout included in an integrated circuit and may be designed to perform a predefined function. As illustrated in FIG. 10, the method of manufacturing the integrated circuit IC may include a plurality of operations S51 to S55.

A cell library (or a standard cell library) D12 may include information, for example, information on a function, a characteristic, and a layout, about the standard cells. In some example implementations, a flip-flop described above with reference to the drawings, in other words, a flip-flop including a master latch and a slave latch, may be included in the integrated circuit IC as the standard cell. For example, the cell library D12 may include information about cells corresponding to the flip-flop described above with reference to the drawings. Accordingly, the integrated circuit IC may provide reduced power consumption.

A design rule D14 may include requirements that the layout of the integrated circuit IC is to comply with. For example, the design rule D14 may include requirements for a space between patterns in a layer, a minimum width of a pattern, a routing direction of a wiring layer, and the like. In some example implementations, the design rule D14 may define a minimum spacing within a track of a wiring layer.

In operation S51, a logic synthesis operation of generating netlist data D13 from register-transfer level (RTL) data D11 may be performed. For example, a semiconductor design tool (for example, a logic synthesis tool) may perform logic synthesis from the RTL data D11 written in a very-high-speed integrated circuit (VHSIC) hardware description language (VHDL) and a hardware description language (HDL) such as Verilog by referencing the cell library D12 and may generate the netlist data D13 including a bitstream or a netlist. The netlist data D13 may correspond to an input of placing and routing to be described below.

In operation S52, the standard cells may be placed. For example, a semiconductor design tool (for example, a place and route (P&R) tool) may place the standard cells used in the netlist data D13 by referencing the cell library D12. In some example implementations, the semiconductor design tool may place the standard cells in rows extending in parallel to each other, and the placed standard cells may be supplied with power from a power rail extending along boundaries of the rows.

In operation S53, pins of the standard cells may be routed. For example, a semiconductor design tool may generate interconnections that electrically connect output pins and input pins of the placed standard cells and may generate layout data D15 that defines the placed standard cells and the generated interconnections. The interconnections may include a via of a via layer and/or patterns of wiring layers. In some example implementations, the wiring layers may include a backside wiring layer located below a gate electrode, in addition to a frontside wiring layer located above the gate electrode. For example, the layout data D15 may have a format such as graphic design system (GDSII) and may include geometric information on the cells and the interconnections. The semiconductor design tool may reference the design rule D14 while routing the pins of the cells. The layout data D15 may correspond to an output of placing and routing. Operation S53 alone or operation S52 and operation S53 overall may be referred to as a method of designing an integrated circuit.

In operation S54, an operation of fabricating a mask may be performed. For example, optical proximity correction (OPC) for correcting a distortion such as refraction caused by a characteristic of light in photolithography may be applied to the layout data D15. Patterns on a mask may be defined to form patterns placed on a plurality of layers based on data to which the OPC is applied, at least one mask (or photomask) for forming patterns of each of the plurality of layers may be fabricated. In some example implementations, the layout of the integrated circuit IC may be modified with limitations in operation S54, and modifying the integrated circuit IC with limitations in operation S54 is post-processing for optimizing a structure of the integrated circuit IC and may be referred to as design polishing.

In operation S55, an operation of manufacturing the integrated circuit IC may be performed. For example, the integrated circuit IC may be manufactured by patterning the plurality of layers using at least one mask fabricated in operation S54. For example, a front-end-of-line (FEOL) may include an operation of cleaning a wafer after planarization, an operation of forming a trench, an operation of forming a well, an operation of forming a gate electrode, and an operation of forming a source and a drain. By the FEOL, individual elements, for example, a transistor, a capacitor, and a resistor, may be formed on a substrate. In addition, for example, a back-end-of-line (BEOL) may include an operation of silicidation for gate, source, and drain regions, an operation of adding a dielectric, an operation of planarization, an operation of forming a hole, an operation of adding a metal layer, and an operation of forming a passivation layer. By the BEOL, the individual elements, for example, the transistor, the capacitor, and the resistor, may be connected each other. In some example implementations, a middle-of-line (MOL) may be performed between the FEOL and the BEOL, and contacts may be formed on the individual elements. Subsequently, the integrated circuit IC may be packaged in a semiconductor package and may be used as a component of various applications.

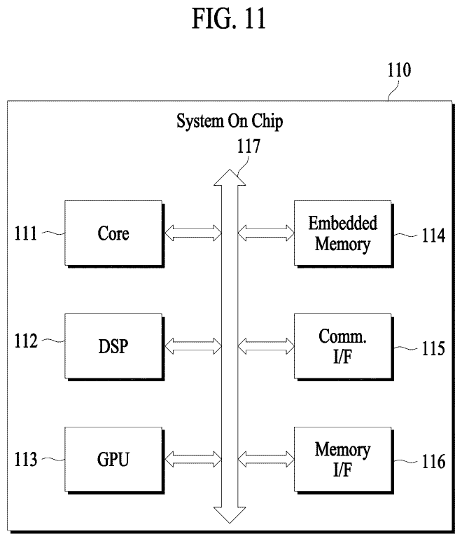

FIG. 11 is a block diagram illustrating a system on chip 110 according to an example implementation. The system on chip (SoC) 110 may refer to an integrated circuit in which components of a computing system or other electronic systems are integrated. For example, an application processor (AP), as an example of the SoC 110, may include a processor and components for other functions. As illustrated in FIG. 11, the SoC 110 may include a core 111, a digital signal processor (DSP) 112, a graphic processing unit (GPU) 113, an embedded memory 114, a communication interface (“Comm. I/F”) 115, and a memory interface (“Memory I/F”) 116. The components of the SoC 110 may intercommunicate through a bus 117. The components of the SoC 110 may include flip-flops described above with reference to the drawings. Accordingly, the components may have low power consumption, and consequently, the efficiency of the SoC 110 may increase.

The core 111 may process instructions and may control operations of the components included in the SoC 110. For example, by processing a series of instructions, the core 111 may run an operating system and may execute applications on the operating system. The DSP 112 may generate useful data by processing digital signals, for example, digital signals provided from the communication interface 115. The GPU 113 may generate data for a video outputted through a display device from image data provided from the embedded memory 114 or the memory interface 116 and may also encode the image data. The embedded memory 114 may store data required for operating the core 111, the DSP 112, and the GPU 113. The communication interface 115 may provide an interface for a communication network or one-to-one communication. The memory interface 116 may provide an interface for external memory of the SoC 110, for example, dynamic random access memory (DRAM) and flash memory.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A flip-flop comprising:
a master latch and a slave latch,
wherein the master latch comprises:
a first circuit configured to generate, based on a data input, a first data signal complementary to the data input; and
a second circuit configured to generate, based on a clock input and the first data signal, a second data signal complementary to the first data signal and a clock signal complementary to the clock input,
wherein the slave latch is configured to receive the clock signal through a first node and to generate a data output by latching a third data signal based on the clock input, the second data signal, and the clock signal, wherein the third data signal is complementary to the second data signal, and
wherein the second circuit is further configured to float the first node based on the first data signal and the third data signal.

2. The flip-flop of claim 1, wherein the second circuit is configured to block a pull-up of the first node based on both the first data signal and the third data signal and on the clock input being at a low level.

3. The flip-flop of claim 2, wherein the second circuit comprises:
a first p-channel field effect transistor (PFET) configured to receive the clock input and a second PFET configured to receive the first data signal, the first PFET and the second PFET being connected in series between a first power node and the first node, wherein the first power node is configured to supply a positive supply voltage; and
a third PFET configured to receive the third data signal, wherein the third PFET is connected in parallel with the second PFET.

4. The flip-flop of claim 1, wherein the second circuit is further configured to:
generate a fourth data signal that is complementary to the data input based on the clock input, the first data signal, and the clock signal; and
pull up the first node based on the fourth data signal being at a low level.

5. The flip-flop of claim 4, wherein the second circuit includes a PFET configured to receive the fourth data signal, wherein the PFET is connected between a first power node and the first node, and the first power node is configured to supply a positive supply voltage.

6. The flip-flop of claim 1,
wherein the second circuit is further configured to generate a fourth data signal that is complementary to the data input based on the clock input, the data input, and the clock signal, and pull up the first node based on the fourth data signal being at a low level,
wherein the second circuit includes a first inverter configured to generate the second data signal based on the fourth data signal.

7. The flip-flop of claim 4, wherein the second circuit is further configured to pull down the first node based on both the clock input and the fourth data signal being at a high level.

8. The flip-flop of claim 4, wherein the second circuit includes a first n-channel field effect transistor (NFET) configured to receive the clock input and a second NFET configured to receive the fourth data signal, wherein the first NFET and the second NFET are connected in series between a second power node and the first node, and the second power node is configured to supply a negative supply voltage.

9. The flip-flop of claim 1, wherein the second circuit includes a second inverter configured to receive the first data signal.

10. The flip-flop of claim 1, wherein the first circuit is configured to:
generate, based on a scan enable input being at a low level, the first data signal complementary to the data input; and
generate, based on the scan enable input being at a high level, the first data signal complementary to a scan input.

11. A flip-flop configured to generate a data output by latching a data input based on a clock input, the flip-flop comprising:
a master latch configured to generate, based on the data input and the clock input, a first data signal complementary to the data input, a second data signal complementary to the first data signal, and a clock signal complementary to the clock input; and
a slave latch configured to receive the clock signal through a first node and to generate the data output by latching a third data signal based on the clock input, the second data signal, and the clock signal, the third data signal being complementary to the second data signal,
wherein the master latch is further configured to float the first node based on the first data signal and the third data signal.

12. The flip-flop of claim 11, wherein the master latch is configured to block a pull-up of the first node based on both the first data signal and the third data signal and on the clock input being at a low level.

13. The flip-flop of claim 11, wherein the master latch is further configured to:
generate a fourth data signal complementary to the data input based on the clock input, the first data signal, and the clock signal; and
pull up the first node based on the fourth data signal being at a low level.

14. The flip-flop of claim 13, wherein the master latch is further configured to pull down the first node based on both the clock input and the fourth data signal being at a high level.

15. The flip-flop of claim 11, wherein the master latch is configured to:
generate, based on a scan enable input being at a low level, the first data signal complementary to the data input; and
generate, based on the scan enable input being at a high level, the first data signal complementary to a scan input.

16. A method of generating a data output by latching a data input based on a clock input, the method comprising:
generating, based on the data input, a first data signal;
generating, based on the clock input and the first data signal, a second data signal complementary to the first data signal and a clock signal complementary to the clock input; and
generating the data output by latching a third data signal based on the clock input, the second data signal, and the clock signal, wherein the third data signal is complementary to the second data signal,
wherein generating the second data signal and the clock signal comprises floating, based on the first data signal and the third data signal, a first node, and wherein the clock signal is generated at the first node.

17. The method of claim 16, wherein floating the first node comprises blocking a pull-up of the first node based on both the first data signal and the third data signal and on that the clock input is at a low level.

18. The method of claim 16, wherein generating the second data signal and the clock signal further comprises:
generating a fourth data signal complementary to the data input based on the first data signal and the clock signal; and
pulling up the first node based on the fourth data signal being at a low level.

19. The method of claim 18, wherein generating the second data signal and the clock signal further comprises pulling down the first node based on both the clock input and the fourth data signal being at a high level.

20. The method of claim 16, wherein generating the first data signal comprises:
generating, based on a scan enable input being at a low level, the first data signal complementary to the data input; or
generating, based on the scan enable input being at a high level, the first data signal complementary to a scan input.
